(19) United States
(12) Patent Application Publication
(10) Pub. No.: US 2026/0327155 A1
(43) Pub. Date: Oct. 22, 2026

(54) CERAMIC SURFACES FOR VAPOR CHAMBERS AND HEAT PIPES IN THERMAL MANAGEMENT

(71) Applicant: THE BOARD OF TRUSTEES OF THE UNIVERSITY OF ILLINOIS, Urbana, IL (US)

(72) Inventors: Constantine MEGARIDIS, Urbana, IL (US); Arani MUKHOPADHYAY, Urbana, IL (US); Sreya SARKAR, Urbana, IL (US); Anish PAL, Urbana, IL (US)

(21) Appl. No.: 19/486,789

(22) PCT Filed: May 30, 2024
(86) PCT No.: PCT/US2024/031659

§ 371 Date: Nov. 21, 2025

Related U.S. Application Data
(60) Provisional application No. 63/469,723, filed on May 30, 2023.
(60) Provisional application No. 63/612,022, filed on Dec. 19, 2023.

(51) Int. Cl. C04B 41/45; C04B 41/00; C04B 41/48

(52) U.S. Cl. CPC C04B 41/4572; C04B 41/0036; C04B 41/009; C04B 41/4846

(57) ABSTRACT

Wick-free vapor chambers and components thereof are provided, that include a wettability-patterned condenser configured to control vapor condensation, and a wettability-patterned evaporator, lire wettability-patterned evaporator is configured to: (i) accept condensate from the wettability-patterned condenser and (ii) transport the formed condensate on the wettability-patterned evaporator. A surface of the wettability-patterned evaporator that is configured to accept and transport the condensate includes a hydrophobic material disposed on a ceramic substrate, lire hydrophobic material may be patterned on the ceramic substrate to define the wettability pattern of the wettability-patterned evaporator. Also provided are methods of fabricating elements of such vapor chambers.

### STATEMENT OF RELATED APPLICATIONS

The present disclosure claims priority to the following U.S. Provisional Patent Applications, each of which is herein incorporated by reference in its entirety: U.S. Provisional Patent Application No. 63/469,723 filed May 30, 2023, entitled Ceramic Surfaces for Vapor Chambers and Heat Pipes in Thermal Management; and U.S. Provisional Patent Application No. 63/612,022 filed Dec. 19, 2023 entitled Ceramic Surfaces for Vapor Chambers and Heat Pipes in Thermal Management.

The present disclosure is related to PCT/US21/51602, which is incorporated herein by reference in the entirety and which is related to the following U.S. Provisional Patent Applications, each of which is herein incorporated by reference in its entirety: U.S. Provisional Patent Application No. 63/082,250 filed Sep. 23, 2020, entitled Vapor Chamber/Heat Spreader With Wickless Wettability-Patterned Condenser and Related Applications; U.S. Provisional Patent Application No. 63/194,094 filed May 27, 2021, entitled Vapor Chamber/Heat Spreader With Wickless Wettability-Patterned Condenser and Related Applications; and U.S. Provisional Patent Application No. 63/197,173 filed Jun. 4, 2021, entitled Vapor Chamber/Heat Spreader With Wickless Wettability-Patterned Condenser and

### RELATED APPLICATIONS

### Field of the Invention

The disclosure herein relates generally to heat transfer and thermal management, and in particular, to vapor chambers with ceramic substrates that facilitate heat transfer encountered in thermal management.

### Background

Thermal management in electronic and related systems, such as fluid or gas systems, can include heat sinks and other fluid-containing thermal management devices, such as vapor chambers. Vapor chambers may be formed of thermally conductive materials, which may also be electrically conductive, such as metals. Existing thermal management systems exhibit a number of shortcomings, including but not limited to degradation of components and overheating. The high electrical conductivity of some materials used to fabricate vapor chamber components raises the risk of short circuiting, which can have consequences for the electronics that such vapor chambers thermally protect.

### SUMMARY

In accordance with the principles herein, thermal management systems and components may benefit by incorporating one or more ceramic materials exhibiting high thermal conductivity, low electrical conductivity, and coefficients of thermal expansion that better match, or can be tailored to better match, the coefficients of thermal expansion of various electronic substrate materials. The use of such materials can thus allow electronic components to be disposed directly or otherwise intimately in contact therewith, thereby increasing the case with which heat is conducted from the electronics to the thermal management components without the risk of electrically shorting the electronics. For example, ceramic substrates can be used in conjunction with vapor chambers and/or other thermal management components.

Such components may be used in a variety of applications, such as in the microelectronics arena, servers, data centers, high-power displays, rapid battery-charging stations, and the like. Examples of such ceramic materials (e.g., non-oxide ceramic materials) as described herein can include ceramic materials with a thermal conductivity between 100 W/m-K and 2000 W/m-K, like aluminium nitride (AlN), silicon carbide (SiC), boron nitride (BN), and boron arsenide (BA), among other possibilities.

The use of such ceramic materials in thermal management systems and components, especially those used to transport heat away from electronic devices, allows them to have various improved properties, including increased thermal conductivity, being electrically insulating, and having a coefficient of thermal expansion that is better-matched to the electronic devices (e.g., to the coefficient of thermal expansion of a silicon, gallium nitride, or other semiconductor substrate material). Accordingly, the use of ceramic materials may allow for a reduced size and/or complexity of thermal management systems, for example by enabling wick-free vapor chambers, and/or by enabling fabrication of electronic devices directly on the ceramic materials (e.g., by adhering the electronic devices directly to the ceramic material, by growing or otherwise disposing semiconductor material on the ceramic material and forming electronic devices therefrom, and/or by doping the ceramic material or using an intrinsically semiconductive ceramic material and forming electronic devices therein). Finally, methods to prepare the ceramic materials, such as laser passivation and/or texturing of AlN or other water-reactive ceramic materials, may include fewer steps, be more environmentally friendly, and be more scalable than alternative techniques used to prepare materials for thermal management systems.

Accordingly, a first example embodiment includes a wick-free vapor chamber including: a wettability-patterned condenser configured to control vapor condensation; and a wettability-patterned evaporator configured to: (i) accept condensate from the wettability-patterned condenser and (ii) transport the formed condensate on the wettability-patterned evaporator, wherein a surface of the wettability-patterned evaporator that is configured to accept and transport the condensate comprises a hydrophobic material disposed on a ceramic substrate, and wherein the hydrophobic material is patterned on the ceramic substrate to define the wettability pattern of the wettability-patterned evaporator.

A second example embodiment includes a wettability-patterned evaporator configured to: (i) accept condensate and (ii) transport the condensate on the wettability-patterned evaporator, wherein a surface of the wettability-patterned evaporator that is configured to accept and transport the condensate comprises a hydrophobic material disposed on a ceramic substrate, and wherein the hydrophobic material is patterned on the ceramic substrate to define the wettability pattern of the wettability-patterned evaporator.

A third example embodiment includes a method of manufacture for a wettability-patterned plate, comprising: processing a ceramic substrate with a laser to impart a surface roughness on the surface of the ceramic substrate to create an oxide passivation layer on the surface of the ceramic substrate; coating the surface of the ceramic substrate with a hydrophobic material; and patterning the hydrophobic material to create wettability patterned regions on the surface of the ceramic substrate, wherein the hydrophobic material is patterned on the ceramic substrate to define the wettability pattern of the wettability-patterned plate.

These as well as other aspects, advantages, and alternatives will become apparent to those of ordinary skill in the art by reading the following detailed description with reference where appropriate to the accompanying drawings. Further, it should be understood that the description provided in this summary section and elsewhere in this document is intended to illustrate the claimed subject matter by way of example and not by way of limitation.

### BRIEF DESCRIPTION OF THE FIGURES

FIG. 1A illustrates a vapor chamber, in accordance with example embodiments.

FIG. 1B illustrates a vapor chamber, in accordance with example embodiments.

FIG. 1C illustrates a vapor chamber, in accordance with example embodiments.

FIG. 2 illustrates a method, in accordance with example embodiments.

FIG. 3A illustrates a method, in accordance with example embodiments.

FIG. 3B illustrates a method, in accordance with example embodiments.

FIG. 4 illustrates a setup for testing a plate, in accordance with example embodiments.

FIG. 5 illustrates example results.

FIG. 6 illustrates example results.

FIG. 7 illustrates example results.

FIG. 8 illustrates example results.

FIG. 9 illustrates example results.

FIG. 10 illustrates example results.

### DETAILED DESCRIPTION

Examples of systems and methods are described herein. It should be understood that the words “exemplary,” “example,” and “illustrative,” are used herein to mean “serving as an example, instance, or illustration.” Any embodiment or feature described herein as “exemplary,” “example,” or “illustrative,” is not necessarily to be construed as preferred or advantageous over other embodiments or features. Further, the exemplary embodiments described herein are not meant to be limiting. It will be readily understood that certain aspects of the disclosed systems and methods can be arranged and combined in a wide variety of different configurations.

It should be understood that the below embodiments, and other embodiments described herein, are provided for explanatory purposes, and are not intended to be limiting.

### I. OVERVIEW

Incorporating ceramic materials into thermal management systems and components can offer significant benefits for various applications, particularly for use in or with electronic devices. Ceramic substrates, such as those made of aluminium nitride (AlN), silicon carbide (SiC), boron nitride (BN), and/or boron arsenide (BA) can provide enhanced thermal conductivity for heat management in electronic devices while providing electrical insulation and coefficients of thermal expansion matched to the electronic devices (e.g., to a semiconductor substrate material thereof). This allows such electronic devices to be disposed directly on such ceramic substrates, enhancing transport of heat from the devices into the substrate by eschewing intervening layers of material (e.g., to insulate the electronic devices from a conducting substrate, to account for mismatch in thermal expansion) which can impede heat transport and increase the cost of fabrication. Accordingly, this disclosure provides systems and methods for utilizing and further enhancing the properties of non-oxide ceramic materials for phase-change heat-transfer hermetic devices.

In one example, aluminium nitride (AlN), a ceramic with high thermal conductivity, high electrical resistivity, and a coefficient of thermal expansion compatible with silicon, is well-suited for direct-to-chip cooling of electronics, implementation in wide bandgap semiconductors, and for high-temperature heat exchangers. However, AlN readily experiences hydrolysis where contacted by various working fluids (e.g., water-based or otherwise aqueous working fluids) in liquid-cooling applications. A scalable and tunable wettability-patterning approach is provided herein to prepare AlN for such applications. These systems and methods allow for the use of bulk AlN substrates in enhanced two-phase cooling of electronics.

Among other advantages, the systems and methods described herein can reduce or prevent hydrolysis of AlN by aqueous media, enable control over surface roughness, and/or maintain bulk integrity and material properties of the underlying substrate. AlN substrates prepared in this manner can be used to implement spontaneous, pumpless surface liquid transport in wettability-patterned wickless vapor chambers. This transportation of fluid (e.g., a condensate formed on the wettability-patterned surface of a condenser directed to a wettability-patterned surface of an evaporator to be evaporated therefrom) allows the ceramic materials described herein to perform beneficial functions in sealed, phase-change, thermal-management devices (e.g., vapor chambers or heat pipes) that use rapid fluid transport in their multi-phase interior.

### II. EXAMPLE SYSTEMS AND METHODS

In general, vapor chambers are thermal management devices that work as heat spreaders, and may include an evaporator plate and a condenser plate. The evaporator may be connected to a heat source (e.g., a processor or other electronic device) and may transfer the beat to a phase-change fluid or medium (e.g., distilled water) stored at low pressures inside the vapor chamber. In the vapor chamber, the medium continually evaporates (from the evaporator), condenses (at the condenser), and drains back into the evaporator, thereby transferring heat from the evaporator to the condenser and spreading it there. Wick-free vapor chambers generally do not rely on wicks, but incorporate surface modifications (e.g., wettability pattering or engineering) for transporting a working fluid (i.e., condensate) from where it has condensed onto the condenser to where needed (e.g., to hot spots heated by a heat source).

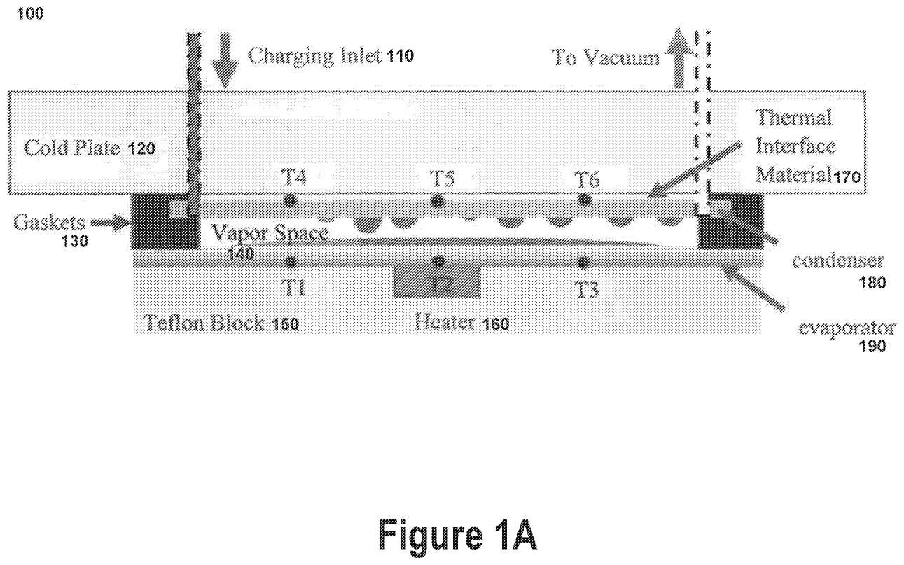

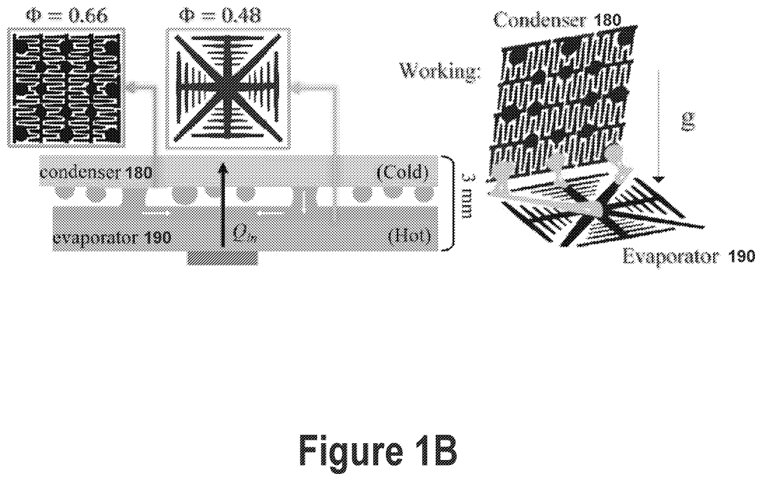

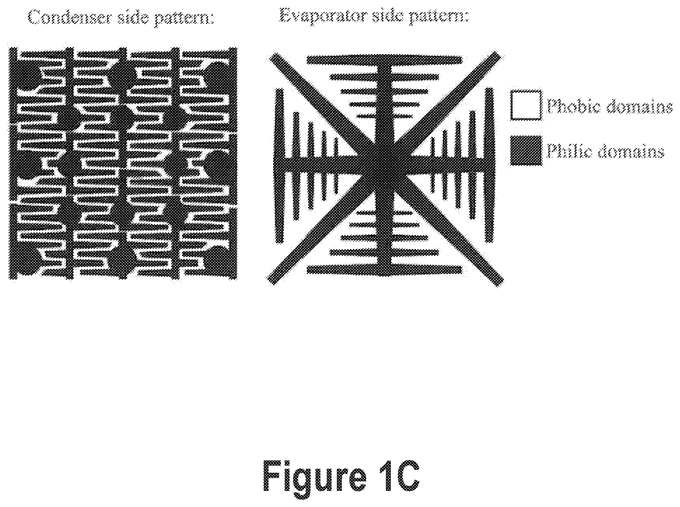

FIG. 1A illustrates an example wick-free vapor chamber 100, which includes charging inlet 110, cold plate 120, gaskets 130, vapor space 140, Teflon block 150, heater 160, thermal interface material 170, condenser 180, and evaporator 190.

Charging inlet 110 may serve as an entry point for introducing a phase-change working fluid (such as distilled water) into vapor chamber 100. During assembly or maintenance of vapor chamber 100, charging inlet 110 may allow for filling or refilling of the fluid. It may be equipped with a sealing mechanism such that, once filled, the inlet can be securely closed to maintain low-pressure or vacuum conditions within the chamber, preventing leakage of the working fluid. Cold plate 120 may serve as a primary interface where heat is absorbed and transferred to evaporator 190 and may be part of or on thermal contact with a heat spreader, heat sink, Peltier device, or other element(s) into which to conduct waste heat.

Gaskets 130 may be sealing elements placed between various components of vapor chamber 100 to prevent leaks and maintain the integrity of the internal vacuum or low-pressure environment. Gaskets 130 help ensure that the working fluid remains contained within the system. Vapor space 140 may be the area within vapor chamber 100 where the phase-change medium evaporates and vapor travels. It provides the volume for the vapor to move from evaporator 190 to condenser 180.

Teflon block 150 may serve as an insulating and/or structural component. Teflon's properties, such as its high temperature resistance and hydrophobicity, may make it suitable for use in vapor chamber 100 to support other components and manage thermal expansion. Heater 160 may be a heat source that provides the thermal energy required for the phase-change medium to evaporate, e.g., a processor, amplifier, oscillator, power supply, or other electronic component(s). Thermal interface material 170 may be placed between a beat source (e.g., heater 160) and cold plate 120 to enhance thermal conductivity. It reduces thermal resistance at the interface, improving efficient heat transfer from heater 160 to cold plate 120 via evaporator 190 and condenser 180.

Condenser 180 may be a part of vapor chamber 100 where the vaporized working fluid condenses back into liquid form. It typically has a high surface area and may include structures (e.g., wettability patterning) to facilitate heat dissipation into the surrounding environment and/or collection of the condensate and transport thereof back to the evaporator 190. Evaporator 190 may be a part of vapor chamber 100 where the liquid phase-change medium absorbs heat and evaporates. It may be directly connected to heater 160 (e.g., one or more elements of the heater 160 may be grown on, grown from, formed in, adhered to, or otherwise disposed on the evaporator 190). The design of evaporator 190 may include surface modifications to enhance wettability, prevent chemical degradation by the working fluid, and improve efficient evaporation and fluid transport.

In some examples, thermocouples may be located both on condenser 180 (T4-T6) and evaporator 190 (Tl-T3) of vapor chamber 100 to facilitate measurement of temperature at various locations of the device 100.

FIG. 1B illustrates the example wick-free vapor chamber 100 and aspects of the operation thereof in additional detail.

Condenser 180 and/or evaporator 190 include wettability-patterned surfaces that enable enhanced condensation and condensate resupply back to the heater. As shown, these may include a coupling mechanism for water (or other working or charging fluid) resupply from the condenser patterns to the evaporator patterns. Thermal resistances of the vapor chamber may be computed for a vapor chamber with or without wettability patterns, with the thermal resistance of a vapor chamber that includes wettability patterns as described herein being enhanced (i.e., reduced) relative to chambers lacking such patterns.

FIG. 1C illustrates an example of wettability patterns (which may also be referred to as “wettability engineered surfaces”). Such complementary wettability patterns as may be found in a wick-free vapor chamber on the evaporator and condenser to aid, among other things, transportation of phase changing fluid to hot spot(s) and to increase the uniformity of condensation, respectively.

A vapor chamber as described herein (e.g., 100) may be wick-free and may include a wettability-patterned condenser 180 configured to control vapor condensation and a wettability-patterned evaporator 190. Wettability-patterned evaporator 190 may be configured to: (i) accept condensate from wettability-patterned condenser 180 and (ii) transport the condensate across the wettability-patterned evaporator 190 (e.g., to one or more hot spots). A surface of wettability-patterned evaporator 190 may be configured to accept and transport the condensate and may include a hydrophobic material disposed on a ceramic substrate. The hydrophobic material may be patterned on the ceramic substrate to define the wettability pattern of wettability-patterned evaporator 190.

In some cases, the ceramic substrate may include aluminium nitride (AlN). AlN and other non-oxide ceramics provide beneficial thermal conductivity, electrical conductivity, dielectric strength, coefficient of thermal expansion matching, and other benefits relative to their use as the evaporator of a vapor chamber as described herein when used to transport heat away from electronics disposed on the ceramic evaporator. However, such materials often exhibit susceptibility, especially at elevated temperatures, to reaction with distilled water or other working fluids used in vapor chambers. Accordingly, a surface of the AlN or other non-oxide ceramic substrate as described herein that is configured to accept and transport the condensate may include an oxide passivation layer to prevent hydrolysis of the working fluid and to facilitate wetting of the AlN substrate by the working fluid (by enhancing the roughness of the surface of the AlN substrate). In some examples, the oxide passivation layer may be thin. In some examples, the surface of the AlN substrate has a surface roughness between 0.1 μm and 200 μm. In some examples, the AlN substrate may have a thermal conductivity between 150 Watts/meter-Kelvin (W/m-K) and 350 W/m-K. In some cases, the AlN substrate may have a dielectric strength between 1×10⁷ Volts/meter (V/m) and 2×10⁷ V/m.

In some examples, the ceramic substrate comprises a non-oxide ceramic with a thermal conductivity between 100 W/m-K and 2000 W/m-K. In some examples, the ceramic substrate includes silicon carbide (SiC).

In some cases, a surface of wettability-patterned condenser 180 may include a second ceramic substrate and a patterned hydrophobic material disposed thereon. In some cases, the hydrophobic material may include a fluorinated polymer, such as polytetrafluoroethylene (PTFE). Other techniques for hydrophobizing substrates are possible. This layer may form a stable and durable barrier that prevents condensate from adhering to the surface, thereby aiding efficient condensation and reducing the risk of fouling. Superhydrophilic surfaces exhibit an affinity for water, enabling rapid condensation and drainage by promoting the formation of a thin, uniform film of condensate. This combination of surface modifications may enable the condenser to achieve improved performance.

In some cases, vapor chamber 100 may include a heat source (e.g., heater 160) that is thermally coupled to the ceramic substrate. For the purposes of this disclosure, heater 160 may refer to one or more heat sources, and may include a test heat source or an electronic device or component, Wettability-patterned evaporator 190 may be configured to transport the condensate formed on wettability-patterned evaporator 190 to a portion (e.g., one or more hot spots) of wettability-patterned evaporator 190 that is heated by the heat source. In some cases, the heat source may include an electronic device. For the purposes of this disclosure, the term electronic device may be a circuit and/or multiple devices, e.g., one or more patterned pieces of silicon or some other semiconductor material patterned to form respective electronic devices (e.g., processors, microcontrollers, graphics processing units, switch-mode power supplies) and/or one or more such devices or components thereof (e.g., transistors) formed directly on or in the ceramic material of the evaporator 190.

In some cases, the electronic device may be fabricated on the ceramic substrate. For example, conductive and/or semiconductive layers could be deposited directly onto the ceramic substrate using methods like sputtering, chemical vapor deposition, physical vapor deposition, or other methods, followed by patterning through photolithography, ion beam etching, or other patterning techniques. Dielectric and/or conductive (e.g., metal routing) layers could be added, and semiconductor elements could be deposited and patterned. In some cases, such fabricated electronic devices may include devices (i) etched into the ceramic material, (ii) grown and/or formed on the ceramic material, (iii) thermally connected to the ceramic material (e.g., by being placed on and then adhered to the ceramic material by an adhesive, pressure, sintering, a mechanical coupling, or some other means), and/or (iv) disposed on the ceramic material by some other means.

### Example Material Preparation and Wettability Patterning

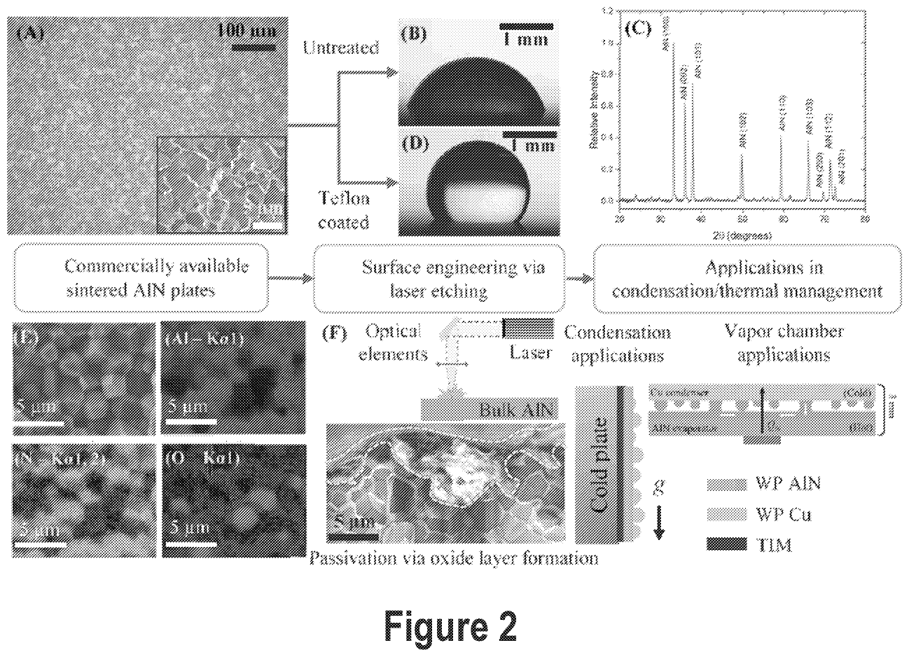

FIG. 2 illustrates steps for preparing materials for use in thermal management, in accordance with example embodiments. For example, the steps of FIG. 2 (and/or other steps not explicitly shown) may be used as part of a method for preparing and/or wettability patterning a ceramic substrate (e.g., AlN) for use in a wick-free vapor chamber like the one discussed in relation to FIGS. 1A, 1B, and IC. In some cases, a wick may be included in such a vapor chamber (e.g., by applying a wick on top of the ceramic substrate). Other types of vapor chambers and/or uses for these systems and methods are possible and within the scope of this disclosure.

The steps of such a method may include processing a ceramic substrate (e.g., AlN) with a laser to alter a surface roughness of a surface of the ceramic substrate and to create an oxide passivation layer on the surface of the ceramic substrate. Such a method can also include coating the passivated surface of the ceramic substrate with a hydrophobic material and patterning the hydrophobic material to create wettability patterned regions on the surface of the ceramic substrate, where the pattern of the hydrophobic material on the ceramic substrate defines the wettability pattern of the wettability-patterned plate formed via the method.

In some cases, the surface may be functionalized either chemically or physically to control the interaction of fluids on the surface. In some cases, such functionalization is brought about by laser processing, chemical treatments, or other tooling and machining to impart a specified finite roughness at the micro/nanoscale. In some cases, such surface functionalization enhances heat transfer across the solid-fluid boundary layer and/or enhances wetting of the surface by the working fluid and transport of the working fluid along the surface (e.g., to hot spot(s)). In some cases, such functionalization prevents chemical interaction (e.g., hydrolysis) between the fluid and the solid substrate.

For example, sintered AlN plates may be first treated with different laser ablation parameters (e.g., power and raster-line spacing) to generate stable oxide layers, which may be characterized for surface uniformity. The functionality of these laser-ablated surfaces can be analyzed via high-speed imaging of microdroplet transport on wettability-confined tracks laid on a hydrophobic AlN background. This can facilitate spontaneous directional pumpless transport of water droplets on such wettability patterned AlN surfaces, e.g., from locations on an AlN evaporator plate at which condensate is received from a condenser plate to one or more hot spots on the evaporator plate to which electronic device(s) deliver heat.

In some cases, particles may be sintered on top of the ceramic substrate to achieve surface roughness. In some cases, surface roughness could be created via laser machining, chemical etching, milling or other techniques known to impart surface roughness of the order of a few hundred microns or lower and/or to impart regular micro-/nano-scale surface texturing or creating homogeneous/heterogeneous roughness.

These methods provide a tunable control of the wettability of hydrolysis-arrested bulk AlN substrates, while retaining some or all of the properties of the bulk material (e.g., thermal and electrical conductivity, thermal coefficient of expansion) under the thin passivation layer. Two thermal management applications with such wettability engineered and hydrolysis-resistant AlN surfaces were evaluated for engineering applications. First, an environmental chamber was used to evaluate the heat transfer performance during condensation on a wettability-patterned AlN plate in different environmental conditions. To further explore the feasibility of AlN ceramics in vapor chambers, tests were carried out in a wettability-patterned wick-free vapor chamber comprising an AlN evaporator and a copper condenser, as shown in FIGS. 1A and 1B.

To impart desired wettability characteristics, AlN substrates may be modified according to some or all of the steps of FIG. 2. A Ytterbium fiber (1060-1080 nm) pulsed laser may be used to induce surface passivation, which can lead to formation of a stable oxide layer (thus reducing or preventing hydrolysis of distilled water or other working fluids) making the surface chemically inert, while preserving the desirable properties (e.g., low electrical conductivity and high thermal conductance) of the underlying bulk material. Laser-induced surface passivation can also impart controlled microscale roughness, facilitating tunable wettability modification of the AlN surface. Such roughened substrates can be rendered hydrophobic by overlaying a thin film of fluorinated polymer (e.g., Teflon) or some other hydrophobic material (or via other standard techniques of surface wettability modification), which may further reduce the incidence of hydrolysis. Such a methodology of concurrently modifying wettability and preventing hydrolysis in a single step (using, e.g., a laser) can be made economical and scalable.

Turning to FIG. 2, at step (A), commercially available bulk AlN substrates were cleansed and imaged under a scanning electron microscope. A contact angle (CA) of a sessile water droplet on clean as-received sample was measured as 40°±0.7°. At step (F), surface passivation techniques via laser ablation were implemented to form a protective oxide layer on the AlN surface. Cross-sectional SEM and EDS were used to verify the thickness of this layer. This thickness was a few micrometers (marked with dashed lines).

In some cases, a single-step approach to modify AlN substrates may be used, which may concurrently alter a surface roughness and form an oxide layer to reduce hydrolysis. Such roughened substrates can then be spin-coated or otherwise coated with Teflon or some other fluorinated polymer or other hydrophobic substance to impart hydrophobic properties to substrates. Varying laser processing parameters may be employed to improve coverage of the substrate by a layer of aluminum oxide, which can inhibit a working liquid (e.g., water) from reacting with the bulk of such AlN substrates.

Laser processing of the AlN substrates can result in surface passivation with varying roughness and surface coverage. In some cases, overlap of the laser scans may be kept high (~90%) to improve coverage, the power input may be varied from 20% to 50% of 20 W, and the raster line-spacing (l_{w}) may range from 0.01 mm to 0.1 mm. In some cases, surfaces may be sonicated in ethanol to remove the debris deposited during the laser-ablation process, and the samples may be then examined under an optical microscope to determine the surface quality.

In some cases, portions on the AlN surface may be left unprocessed, thus being prone to hydrolysis when in contact with water (this may be verified both from SEM micrographs and from images under an optical microscope). The wettability of the laser-processed samples was confirmed by dispensing water droplets of 4.87 μL on each surface and imaging the spreading characteristics. The observed hemi-wicking on each sample may be influenced by the surface roughness and the chemical properties of the surface. Optical microscopy was used to confirm the alteration of the AlN substrate when smaller raster line spacing was used. In some cases, better wicking may lead to more effective thermal management devices whose operation relies on pool boiling or evaporative heat transfer from thin films.

To develop phobic samples, the laser-processed surfaces may be coated with Teflon (or another material) via spin-coating, as may be done for surface-wettability modification. Such coated samples were examined with an optical goniometer to measure water CAs which quantified each surface's hydrophobicity. In some cases, advancing and receding CA measurements were also be carried out to designate the surface wetting characteristics. In some cases, Teflon-coated AlN surfaces may be “sticky hydrophobic,” featuring high contact angle hysteresis, with the droplet contact line getting pinned to the surface, and thus reducing the measurability of the receding contact angle. This contact-line pinning on hydrophobic surfaces, which is known as the “rose-petal” effect, may be attributed to the Cassie impregnation of the liquid in the substrate surface microstructures.

Once the laser ablation parameters for surface passivation of the AlN substrates were finalized and the wettability characteristics of both hydrophilic and hydrophobic surfaces were determined, the viability of spontaneous directional pumpless transport (SDPT) on such substrates was investigated. In some cases, SDPT harnesses Laplace pressure gradients imposed by the curvature difference in the liquid/gas interface of a water droplet were placed on a hydrophilic wedge to propel the droplet towards the wider end of the track without the aid of external forces (e.g., gravity).

A superhydrophilic herringbone wedge was created via laser ablation on a hydrophobic Teflon-coated AlN background. The final wedge was laid on the hydrophobic AlN background and characterized both via SEM imaging and with a microscope and profilometer. The SEM micrographs confirmed the continuity of the wedge-shaped pattern and showed less exposed AlN surface. Uniformity is beneficial to maintain both physical and chemical integrity of the surface during continued experimentation and during applications in thermal management. The surface profilometry confirmed uniform roughness distribution across the superhydrophilic wedge at an average value of 0.82 μm.

AlN substrates (e.g., of a size of 16 cm²) were tested inside a controlled environment chamber to evaluate surface condensation performance of wettability-patterned metal substrates. The surface engineered samples were affixed on top of a cold plate with zinc oxide (ZnO)) thermal interface material (e.g., 5 W/mK) which may enable a reduced amount of air gaps in between the substrate and the cold plate. The environmental chamber circulated hot and/or humid air, resulting in condensation on the cooled substrate, allowing the collected condensate to be subsequently used for heat transfer performance evaluation of each plate sample.

In some examples, the relative humidity (RH) was fixed at 80%, while the ambient temperature was fixed cither at 30° C., 40° C., or 50° C. These conditions resulted in dew point temperatures of 26.2° C., 35.9° C., and 45.6° C., respectively, below which condensation may take place. Therefore, the cold plate and attached substrate were maintained at 10° C., resulting in uniform condensation from the ambient humid atmosphere. Gravimetric analysis of the collected condensate allowed for a direct correlation with the latent heat transfer through the substrate.

Comparisons of condensation heat transfer rates of laser-passivated Teflon-coated AlN substrates (with or without wettability patterns) were made against a mirror-finish Teflon-coated (hydrophobic) copper substrate (CA~110°). Such analysis allowed for a direct estimation of the amount of condensate that would form on the substrate in the presence of non-condensables (e.g., humid air).

The Teflon coating and laser passivation prevented the collected condensate from chemically interacting with the substrate, which may thus maintain both favorable bulk and surface properties as a result of the method described above. Further, wettability patterning may be implemented on the laser-passivated Teflon-coated plates by selective laser ablation or other patterning techniques to remove the Teflon from the desired locations. This can result in a wettability-patterned substrate, featuring superhydrophilic (or merely hydrophilic) domains on a hydrophobic background.

In some cases, wettability patterns (e.g., as shown in FIG. 1C) may be specified to restrict the maximum size of the droplet in the hydrophobic region, thereby further enhancing the condensation rates and thus improving heat transfer. In some cases, a maximum droplet diameter was restricted by the width of the hydrophobic areas. In some cases, an interdigitated pattern featuring wedges and hydrophilic pathways can be used by harnessing the Laplace pressure gradient, for example as in SDPT. While the hydrophobic regions may enable dropwise condensation (DwC), the superhydrophilic filmwise condensation (FwC) domains may act as efficient condensate transportation pathways, which removed the collected condensate. Condensation heat transfer during DwC or FwC may be limited by the thermal resistances in each mode of condensation.

In some cases, a condensate film may cover the substrate during filmwise condensation, thereby adding to the thermal resistance and decreasing condensation rates. Furthermore, the fast sweeping of droplets in the DwC domains, owing to low surface adhesion, may aid condensation by generating new nucleation sites.

Accordingly, the choice of laser ablation parameters prior to hydrophobization of the surface (via Teflon spin-coating or a similar process), may be chosen based on the desired surface adhesion parameters.

In some cases, Teflon-coated hydrophobic areas may promote DwC, with FwC occurring on the hydrophilic wedge tracks (or “rivers”). The hydrophilic wedge-shaped tracks may aid the faster removal of condensate droplets from the adjacent hydrophobic regions, thereby allowing renewed nucleation and aiding condensation. In experiment, such wettability patterned AlN surfaces outperformed both Teflon-coated substrates. The wettability-patterned hydrolysis-arrested samples with an interdigitated wedge-shaped pattern outperformed the Teflon-coated smooth copper (by ~42.5%) and the Teflon-coated hydrolysis-arrested AlN (by ~12.5%). The improved condensate collection of the hydrophobic AlN samples over the mirror-finish copper samples may be attributed to the higher contact angle of the former surface, which may result in droplets rolling off faster from the condensing surface and therefore promoting the formation of new nucleation sites.

While the disclosure above makes reference to one set of wettability patterns or surface treatments, these examples serves as possible embodiments to illustrate that the systems and methods described herein for patterning of surfaces for condensation enhancement can be achieved with laser-passivated AlN samples (or other ceramic materials).

### Example Applications in Thermal Management

Once wettability patterns have been formed on the AlN surfaces (or other ceramic substrates) of a condenser and/or evaporator plate of a vapor chamber as described herein, such wettability-engineered ceramics can be used in thermal management of electronics (e.g., as discussed in relation to FIGS. 1A, 1B, and IC). For example, wick-free vapor chambers (WF VCs) have exhibited low effective thermal resistances with proven capacity to handle power loads exceeding 200 W. Such vapor chambers may overcome traditional problems of capillary blocking or pressure drops faced by VC systems with wicks.

Accordingly, in some cases the methods described above may additionally or alternatively include obtaining a wettability-patterned condenser configured to control vapor condensation; joining the wettability-patterned evaporator and the wettability-patterned condenser together to form a wick-free vapor chamber; evacuating a vapor space between the surface of the wettability-patterned evaporator and the wettability-patterned condenser using a vacuum pump; and supplying a phase-changing liquid to the vapor space.

In some cases, the method may additionally include thermally coupling an electronic device to the ceramic substrate, wherein the patterning further comprises patterning the hydrophobic material to transport the condensate formed on the wettability-patterned evaporator to a portion of the wettability-patterned evaporator that is heated by the electronic device.

In some cases, WF VCs feature wettability patterns on both the condenser and evaporator side of the system, with the wettability patterns on the cool side enhancing uniform condensation, while the evaporator patterns maintain a continuous supply of the working fluid to the heat input region(s). Wettability-patterned condensers can also be incorporated in hybrid devices, which combine both wickless and wicklined components.

In some cases, such systems have been shown to achieve low cross-plane thermal resistances (<0.01 K/W at 202 W of power input via high frequency switching MOSFETs) in air-cooling of power electronics. The electrically insulating but thermally conductive nature of AlN or similar non-oxide ceramic substrates can beneficial for direct integration with electronics or for direct-to-chip cooling applications, without grounding or other means for electrically isolating the thermal management system from the electronics.

In some cases, the VC (such as vapor chamber 100 of FIG. 1A) may include a wettability-patterned AlN (or other non-oxide ceramic) evaporator paired with a wettability-patterned condenser (composed of, e.g., copper, AlN, or some other material). In some cases, a VC may comprise ceramic components, and in other cases, a VC may comprise a material-hybrid system. The latter may mitigate risks pertaining to the stresses experienced, for example, by an AlN plate owing to a pressure differential from the interior of the VC to the ambient.

In some cases, a vapor chamber as described herein may include an assembled VC on top of a 1 cm² resistive heater (e.g., in order to experimentally assess the thermal and other properties of the VC). As discussed above in relation to FIG. 1A, the VC may be sealed using gaskets, which may allow for faster testing, assembly, and disassembly of flat plate evaporators or condensers. A liquid-cooled plate on top of the condenser side of the VC may allow for faster removal of heat from the system.

In some cases, a cross-plane VC thermal resistance, a metric commonly used to measure heat transfer performance in thermal energy research, may be assessed to measure the improvements provided by the embodiments described herein. The VC thermal resistance can be determined for varying heat inputs and at different charging ratios (CRs).

As an example, a WF VC comprising of a uniformly hydrophilic, laser-passivated AlN evaporator and a hydrophobic mirror-finish Teflon-coated copper condenser, both featuring no wettability patterns, was experimentally assessed. As another example, a VC featuring a wettability-patterned AlN evaporator and a wettability-patterned copper condenser was experimentally assessed.

The WF VC with no patterns achieved a thermal resistance of 0.21 K/W for the lowest power input (10 W) and a CR of 48%. Such a CR may be beneficial for certain VCs, where a decrease in the amount of working fluid in the VC resulted in higher resistances at increased power inputs, possibly owing to dry-out on the evaporator. On the other hand, an increase in the mass of the working fluid (higher CRs) may result in inefficient transport of beat due to an increase in the amount of water on the evaporator.

The wettability-patterned WF VC maintained a uniformly low thermal resistance over a wide range of power loads for various working fluid charging ratios. The patterns on the copper condenser facilitated efficient condensation and drainage of the working fluid, while the patterned evaporator maintained a continuous supply of the working fluid back to the hotspot beneath the heater, thereby reducing thermal dry-outs. The choice of the patterns on the evaporator and condenser side of the WF VC can be specified such that the condenser can drain efficiently onto the opposing evaporator. The lowest thermal resistance observed for the patterned VC was 0.17 K/W at a power input of 90 W. Potentially related to the uniformity of condensation promoted by the patterned condenser and the efficient transport of water on the patterned evaporator, this VC maintained a low thermal resistance for a wide range of power inputs (as contrasted against the VC with uniform wettability components). Thermal dry-out (indicated by evaporator temperatures that exceeded a heater safety threshold) were observed in the patterned WF VC, albeit at much higher powers as compared to the VC with no patterns, thereby confirming the general efficacy of wettability patterns in enhancing VC performance.

While the ceramic materials and processes described herein may be used for thermal management (e.g., in vapor chambers), other uses are possible. For example, ceramic substrates could be used to dissipate heat by interacting with a fluid (e.g., as components in heat-pipes, heat sinks, cold plates, refrigeration technology).

### III. EXPERIMENTAL RESULTS

The use of AlN (or other non-oxide ceramics which act as electrical insulators) avoids the use of an insulator layer or other elements to electrically ground such a ceramic thermal management component from electronics disposed thereon, leading to weight savings as well as reduced assembly space and cost. AlN has a high thermal conductivity and significant electrical resistance, which can result in lowered maximum device temperature when used to form thermal management elements. Metallized ceramic substrates using AlN are well-suited for use in integrated circuit (IC) packages, owing to AlN's high thermal conductivity and thermal expansion coefficient similar to silicon. The similarity of AlN's thermal expansion coefficient with silicon enhances solderability by increasing the thermal cycle fatigue life of the solder bump by 5.5 times.

AlN is known to interact with water and form a variety of oxides, making it susceptible to hydrolysis. Hydrolysis of AlN powders can lead to continuous degradation of the surface or the entire material by formation of boehmite or bayerite. Metallization (or surface passivation) via laser etching as described herein forms a film of Aluminum or a rich mixture of oxides, which can inhibit hydrolysis and allow for safe surface wettability modification of bulk AlN. This allows the surface to handle common phase-change heat transfer liquids (e.g., water) and to avoid chemically interacting with them during enhanced liquid transport via wettability variation. However, such ceramic surfaces are hard, brittle and chemically resistant, making it difficult to create micro or nanoscale roughness in order to, e.g., impart specific surface properties.

According to the methods described herein, AlN surfaces are first modified via laser-induced surface passivation to render them chemically inert (thus preventing hydrolysis), preserving the properties of low electrical conductivity, high thermal conductance, and desirable coefficient of thermal expansion of the underlying bulk material. The wettability of AlN was altered in order to obtain the desired mode of condensation on its surface; dropwise (DwC) on phobic domains, and filmwise (FwC) on philic domains. Superhydrophilic wedge-shaped channels were patterned on a hydrophobic AlN background using laser etching. An environmental chamber was used to evaluate the condensation performance of wettability patterned AlN plate samples featuring varying wettability pattern designs in different environmental conditions.

The environment temperature and relative humidity were set at desired levels and the condensation heat transfer coefficients were estimated. These experiments demonstrated the feasibility of wettability patterning on ceramic surfaces to resist wear over extended periods of application while being thermally conductive, electrically insulating, chemically resistant, and hard.

Substrates of Aluminum-Nitride ceramic (sintered sheets of dimensions 11.43 cm×11.43 cm×0.63 mm, McMaster-Carr, thermal conductivity 180 W/mK, maximum temperature rating of 1298.8° C.) were used. Samples of 3 cm×1 cm in size were first cut using a Disco DAD321 dicing saw with a blade speed of 30,000 rpm and a feed rate of 1 mm/s. Thereafter, these samples were ultrasonicated (PCI Analytics, USB 3.5L H DTC) in Ethanol (Merck Pvt. Ltd.) for 10 min, and then in distilled water (M=18.02 g mol⁻¹, Merck Life Science Pvt. Ltd.) for 10 min.

Bulk unprocessed AlN is known to react with water with the formation of boehmite, bauxite, and other aluminum oxides. Such reactivity is detrimental to surface functionalization and can also affect the bulk material, especially in heat transfer applications at elevated temperatures wherein the reactivity is further enhanced. Accordingly, the sample surfaces were either uniformly spin-coated with Teflon Amorphous Fluoropolymer (AF) (Chemours AF 2400, 1% solution in Fluorinert FC-40) or passivated using laser-induced techniques. Varying laser ablation parameters were employed to ensure complete coverage of the substrate to ensure that there remained a uniform film of aluminum and its oxides to inhibit the phase change heat transport liquid (water) from reacting with the bulk AlN substrate.

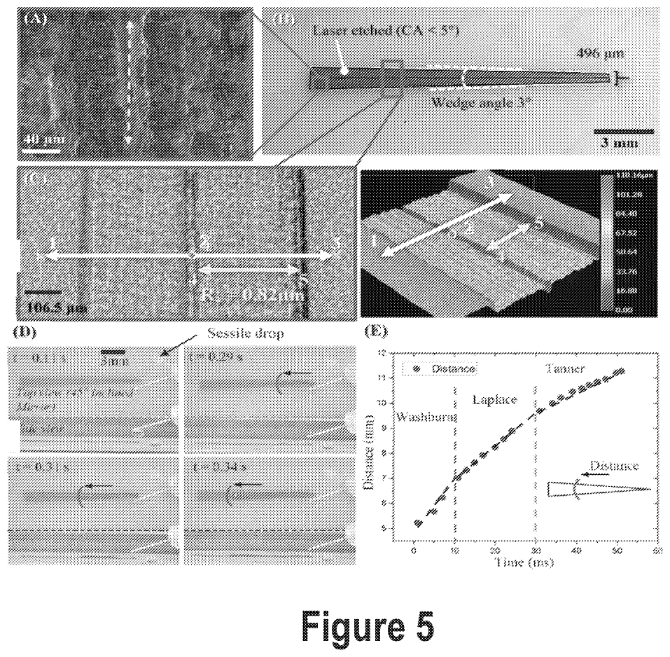

The cleansed AlN substrate was subjected to a variety of laser ablation parameters. For this purpose, a commercial scale industrial pulsed fiber laser marking system (EMS300 20 W Yb: fiber laser, TYKMA Electrox) with a wavelength of ~1060 nm and a resolution of 50 μm was used. Overlap of the laser tracks for each parameter variation was kept constant at 90%. The overlap percent was determined from the laser frequency, raster speed and the spot diameter (or resolution) of the laser beam used for the process. While overlap of the pulses was kept high, different laser parameter settings, namely power input (20, 30, 40 and 50% of the maximum power, 20 W) and a raster line spacing width (l_{w}=0.01 mm and l_{w}=0.1 mm) were varied and tested on the AlN substrate. The developed surface was further sonicated for 20 minutes in ethanol to remove debris commonly deposited during the laser ablation process, and the sonicated samples were then examined under an optical microscope to determine the surface ablation outcome. While a line spacing of 0.01 mm (lower than the laser spot diameter) resulted in uniform coverage of the substrate a greater line spacing (in this scenario 0.10 mm) was seen to leave exposed AlN surfaces which can be prone to hydrolysis when in contact with water. The developed 1 cm×1 cm laser-ablated samples (i-viii in Table 1) were characterized for their hydrophilicity by dispensing a 4.7 μL water droplet at the center and using high-speed imaging of the spreading characteristics. The final shape of the droplet is shown in panel (C) of FIG. 5, with the maximum extension being marked with an arrow.

To develop hydrophobic samples, the laser-passivated surfaces were coated with Teflon via a spin coating process. The contact angle of a 4.7 μL water droplet on the cured and coated samples was measured with an optical goniometer to get an estimate of the surface phobicity. The measured contact angles are demonstrated in panel (A) of FIG. 5. Along with the contact angles, advancing and receding contact angle measurements were also carried out. The contact angles on the various surfaces are listed in Table 1. Note that the contact angle is affected both from the surface chemical characteristics and from the physical parameters, like surface roughness. The surface roughness parameters are also listed in Table 1. The passivated Teflon-coated AlN surfaces behaved as “sticky hydrophobic” and featured high contact angle hysteresis, with the droplet getting pinned to the surface, thus preventing an estimate of the receding contact angle. Such pinning of the contact line (called rose-petal effect) has been observed in earlier research, and may be attributed to Cassie-impregnation of the liquid in the substrate microstructures.

TABLE 1
Contact angle parameters for bare AlN as compared with Teflon-coated
AlN and laser-etched Teflon-coated AlN. All laser-etched surfaces
(if uncoated) show spreading and are superhydrophilic with contact
angles < 5°, and no measurable (very low) receding angles.

| Sample | | l_{w} | Sₐ | S_{z} | | Ad- | Re- |
|---|---|---|---|---|---|---|---|
| Number | Power | (mm) | (μm) | (μm) | Static | vancing | ceding |
| Bulk | | | 1.18 | 6.63 | 40° ± | 70° ± | Pinned |
| uncoated | | | | | 0.1° | 0.2° | |
| Teflon | | | 1.18 | 6.63 | 130° ± | 147° ± | Pinned |
| coated | | | | | 0.1° | 0.1° | |
| (i) | 20% | 0.01 | 0.65 | 6.48 | 113° ± | 147° ± | Pinned |
| | | | | | 0.2° | 0.3° | |
| (ii) | 30% | 0.01 | 1.08 | 8.27 | 149° ± | 164° ± | 141° ± |
| | | | | | 0.1° | 0.1° | 0.2° |
| (iii) | 40% | 0.01 | 1.54 | 16.07 | 123° ± | 155° ± | Pinned |
| | | | | | 0.2° | 0.1° | |
| (iv) | 50% | 0.01 | 1.81 | 13.52 | 138° ± | 160° ± | Pinned |
| | | | | | 0.1° | 0.4° | |
| (v) | 20% | 0.10 | 0.76 | 6.55 | 125° ± | 150° ± | Pinned |
| | | | | | 0.1° | 0.1° | |
| (vi) | 30% | 0.10 | 1.86 | 10.71 | 128° ± | 148° ± | Pinned |
| | | | | | 0.2° | 0.3° | |
| (vii) | 40% | 0.10 | 2.78 | 16.54 | 120° ± | 153° ± | Pinned |
| | | | | | 0.1° | 0.1° | |
| (viii) | 50% | 0.10 | 3.41 | 18.47 | 117° ± | 159° ± | Pinned |
| | | | | | 0.3° | 0.4° | |

Additional experiments were performed using hydrophilic domains with the laser parameter ablation settings of sample (ii), which resulted in improved spreading characteristics. For choosing hydrophobic surfaces, the parameters of sample (ii) were also used due to its high contact angles and low surface frictional forces, which could be beneficial for rapid removal of droplets to enhance phase-change heat transfer.

The samples were then functionalized by spin-coating Teflon Amorphous Fluropolymer (AF) (Chemours AF 2400, 1% solution in Fluorinert FC-40) for 20 s at 2000 rpm on a WS-400-6NPP-Lite spin processor. Each Teflon-coated substrate was then cured by heating on a hot plate in a stepwise manner (20° C./min ramp rate) to first reach the boiling point of the solvent (160° C.) where they were maintained for 10 min, then at the glass transition temperature of Teflon (240° C.) for 5 min, and finally at the adhesion-promoting temperature (330° C.) for 15 min. After this process, the surface of the AlN sample was hydrophobic. When a single water droplet (4.5 μL) was dispensed on this sample, the static contact angle (CA) as measured with an optical goniometer with the sessile droplet method was 130+1.3°.

Next, a fiber laser marking system (EMS400, TYKMA Electrox) was used, which was operated at 20 kHz pulse frequency, 40% power and 100 mm/s rastering speed to apply a wedge pattern (narrow end −496 μm, 1.5 cm long wedge with edge-to-edge angle 3°) on the surface by selectively etching away the Teflon coating and texturing the underlying ceramic surface. This laser-etched area (herringbone-patterned wedge) was superhydrophilic (CA<) 5° and the rest of the Teflon-coated area in the surroundings remained hydrophobic. The sample so obtained was thereafter sonicated in distilled water for 5 min to remove any residual AlN or Teflon particles left from the laser-etching process.

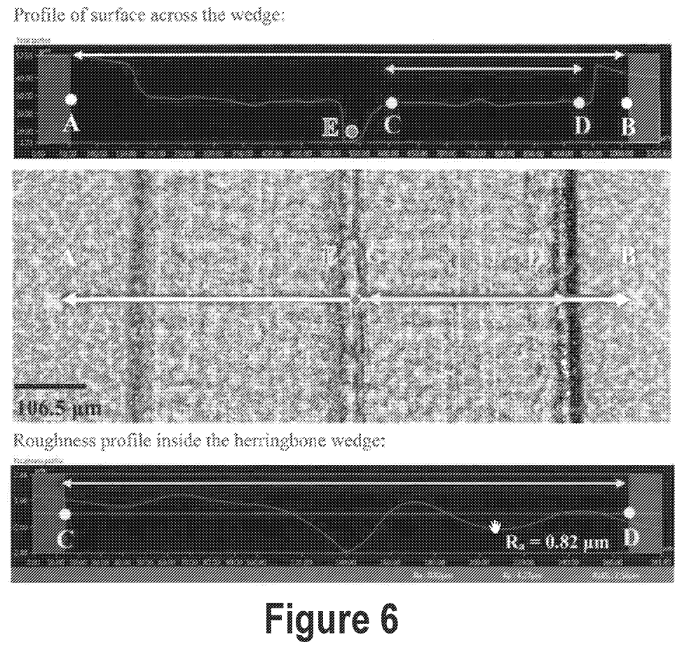

An optical microscope and profilometer (Keyence VHX6000) was used to measure the surface profiles. Typical roughness profiles of the surface are shown (e.g., in FIG. 6), with an Ra (average roughness) of 1.18 μm on the Teflon coated AlN, while the roughness of the laser etched track was found to be 0.82 μm. A scanning electron microscope (SEM) was used to visualize the detailed morphology of the substrate.

The selectively laser-etched wedges on the AlN substrates were used to demonstrate self-propelled droplet transport at room temperature (no phase change). Water droplets (4.5 μL) were dispensed one at a time on the narrower end of the wedge which was kept on a horizontal plane. Each dispensed water droplet spontaneously moved from the narrow end of the wedge to the wider edge without any external force. The liquid, which started in the form of a dispensed droplet, propagated on the wedge as a well-defined bulge (bulk liquid) followed by a trailing liquid film conforming to the track geometry. This pumpless transport from one end of the wedge to the other was affected by the curvature of the liquid volume (Laplace pressure) and was able to overcome opposing forces (e.g., viscous shear) at these length scales. The droplet motion was captured using a high-speed camera setup. The surface was illuminated using an LED light source. To obtain the motion of the three-phase contact-line of the water droplet while it advanced along the wedge track, a plain mirror was placed at an angle of 45° (from horizontal) facing the lens of the camera. This arrangement provided simultaneous side and top views of the droplet spreading, i.e., temporal progress of the liquid front for a single droplet of water (4.5 μL) that moved along the 1.5 cm length of the wedge. The average velocity of the droplet was 23 cm/s, which is comparable to the reported transport velocity of water droplets on similar tracks on metallic surfaces.

The above tests showed that wettability-confined wedge tracks on AlN samples can be patterned by hydrophobization first (deposition of Teflon film) and then laser etching that render the etched domains superhydrophilic and surrounded by a hydrophobic background. Such wettability-patterned AlN surfaces can be used to achieve a combination of dropwise condensation (DwC on hydrophobic Teflon-coated area) and filmwise condensation (FwC on superhydrophilic laser-etched wedge) domains, which can promote condensation heat transfer.

The wedge-equipped sample was subsequently tested in a condensing environment by attaching it to a liquid-cooled plate placed at an inclination of 10° inside an environmental chamber (Espec). The relative humidity (RH) of the chamber was kept constant at 80%, while the ambient temperature (T_{amb}) and the cold-plate temperature (Tc) were varied to obtain various test conditions. DwC was seen around the wedge, which was covered by the condensate film and an increasing amount of water. The drops seen on the hydrophobic area on the AlN sample show that DwC was promoted, while the film on the laser-etched wedge confirmed that that area promoted FwC. Note that the amount of liquid accumulated on the wedge shows that the volume rises from the narrow to the wide end of the track.

Another benefit of using AlN plates in sealed heat transfer devices (e.g., vapor chambers and heat pipes) is their ability to maintain vacuum. AlN samples were subjected to vacuum to check if air could pass through or if they were air-tight. The setup shown (e.g., as depicted in FIGS. 1A and 1B) was used to perform these tests. The sample was placed firmly onto a gasket (Viton Fluoroelastomer, 75A Durometer Shore hardness) and the vacuum pump was switched on. The pressure gauge was monitored until a very low reading (<29 inch Hg) was obtained. A valve connecting the substrate to the pump was turned off, and the system was left undisturbed for ~36 hours. After this period, no difference in the pressure reading was observed, demonstrating that the AlN samples were air-tight and can be used as components of vapor chambers and heat pipes.

These AlN samples were incorporated into a wick-free vapor chamber. Wick-free vapor chambers are thermal management devices that work as heat spreaders, and do not rely on wicks, but incorporate surface modifications for transporting the working fluid where needed. The evaporator, which sits atop a beat source, transfers the heat to a phase-change medium (herein distilled water), stored at low pressures inside the vapor chamber. The water continually evaporates (from the evaporator), condenses (at the condenser), and drains back into the evaporator, thereby efficiently transferring heat from the evaporator to the condenser and spreading it there.

Tests the vapor chamber (VC), an AlN sample was cut into size (7 cm×6.3 cm) as a rectangular evaporator. Thereafter, the sample was subjected to ultrasonication first in ethanol and then in distilled water, both for 10 minutes. This sample was then further processed, using the techniques described above to make them either uniformly superhydrophilic or to render wettability patterns on the substrate. The surface passivated wettability patterned substrates were then was dried thoroughly with nitrogen (99.99% N₂ from Praxair), and then loaded in the vapor chamber test setup (as shown in FIG. 1A), to act as the evaporator side of the VC. Example wettability patterns used in the design of the vapor chamber are shown elsewhere herein. The AlN evaporator was coupled with a wettability-patterned copper condenser. The vacuum pump connecting the setup was then switched on, and the air from inside the chamber was evacuated until a pressure gauge reading <29 in Hg was obtained. The VC was then charged by allowing distilled water to enter via the charging port. The developed vapor chamber had a vapor space of 5 cm×5 cm×1 mm, and an overall thickness of 2.4 mm. The VC was placed on top of a 10Ω resistive heater (Component General, CPR-375-1) of dimensions 9.5 mm×9.5 mm×1.0 mm. Thermocouples placed at various locations on the VC (marked by T1-T6, in FIG. 1), were used to record temperatures for varying power inputs to the VC and at different charging ratios (defined as the ratio of the volume of the phase-changing liquid to the entire vapor space of the VC).

The thermal resistance (in K/W) of the vapor chamber (defined as the difference between T2 and the average condenser temperature, divided by the power input to the system) was evaluated for various charging ratios and at varying power inputs. An optimum charging ratio was observed at around ~48% where thermal resistance dropped to 0.17 for thermal load of ~90 W. These experiments demonstrate, among other things, that (i) areas of different levels of wettability can be fabricated on AlN samples, and (ii) AlN plates can maintain vacuum for prolonged periods, allowing thing to be used to form devices operating at pressures below 1 atm. These experiments demonstrate the feasibility of incorporating AlN surfaces as described herein in thermal management devices whose operation relies on phase change.

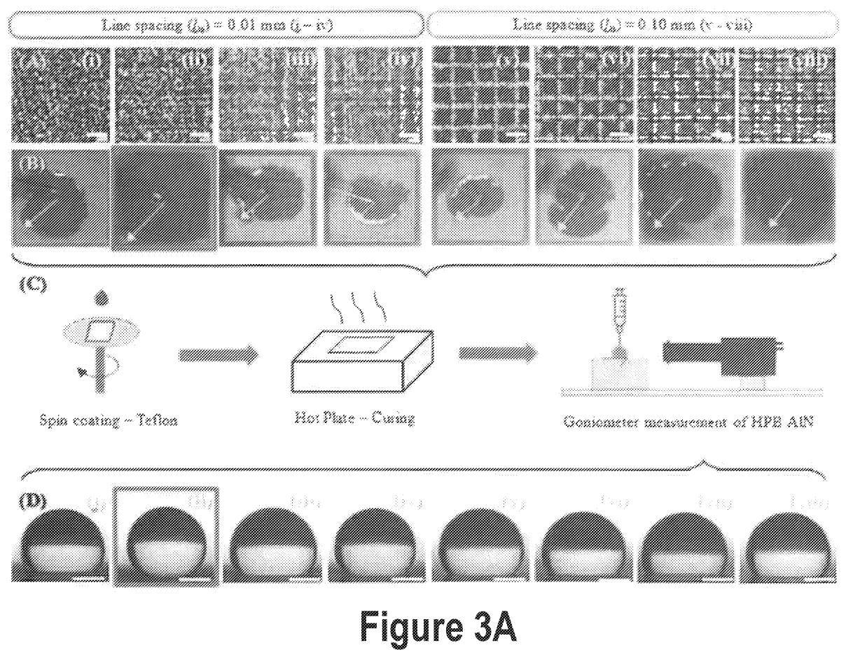

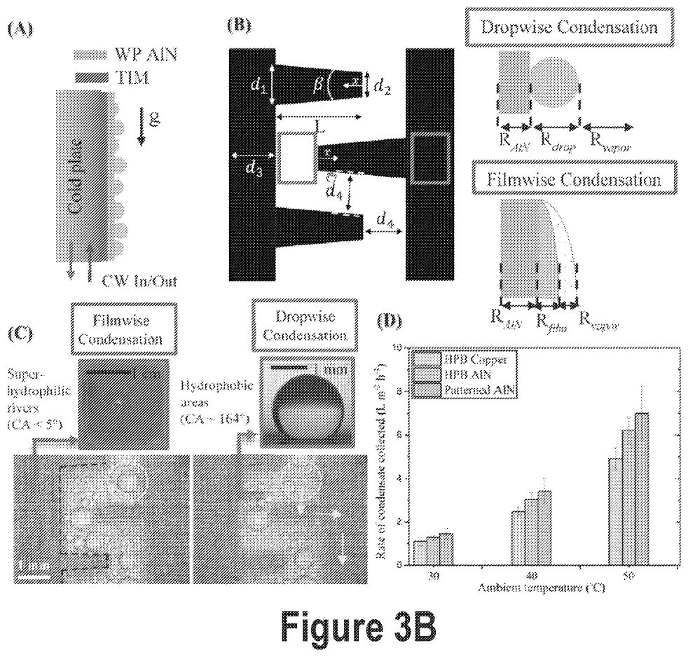

FIGS. 3A and 3B illustrate a method for preparing a plate, in accordance with example embodiments.

FIG. 3A depicts: (A) AlN samples were characterized for different laser ablation parameter settings (Samples i-viii, scale bars denote 100 μm). Variations of the laser settings resulted in different surface roughnesses. (B) To characterize the surface wettability, spreading parameters were studied on 1 cm×1 cm laser-ablated AlN substrates with a high-speed camera. The final wetting state for each scenario is shown below the respective images. (C) Laser-ablated samples (i-viii) were also spin coated with Teflon and cured on a hot plate, to turn them hydrophobic. (D) Water contact angles on the substrates were studied with an optical goniometer (Scale bar 2 mm). Sample ii (in the box) outperformed the other samples both in terms of spreading and had a greater contact angle when coated with Teflon.

FIG. 3B depicts: (A) Schematic of wettability-patterned (WP) AlN substrate mounted vertically in an environmental chamber, which maintained constant relative humidity RH=80% for different ambient temperatures, while the samples were maintained at 10° C. using an attached cold plate. (B) The interdigitated pattern comprised of both hydrophobic (white) and superhydrophilic (black) domains enhanced condensation heat transfer performance. The geometric features of the pattern are marked in the schematic. The thermal resistances (RAIN, Rdrop, Rvapor, Rfilm) during condensation in either FwC or DwC modes have also been marked in separate schematics. (C) Experimental observations confirmed dropwise condensation on the Teflon-coated AlN domains, with filmwise condensation occurring on the laser-ablated (philic) sections. (D) Performance of the samples was evaluated using the condensate mass collected per hour from each sample.

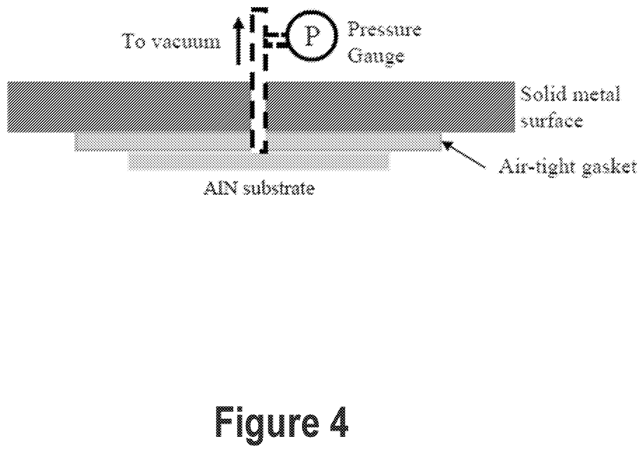

FIG. 4 depicts an experimental setup to test whether AlN samples can hold vacuum. An air-tight gasket ensured that air was only able to leak into the system if the substrate was porous.

FIG. 5 depicts aspects of the use of laser ablation on Teflon-coated AlN samples to obtain superhydrophilic tracks for spontaneous pumpless fluid transport. (A) SEM micrograph of the laser-ablated superhydrophilic tracks (a raster line has been marked by a dashed line). (B) A wedge track (angle 3°) carved by repeated passes of the laser: the darker area is superhydrophilic (CA<5°), while the surrounding lighter area (Teflon-coated AlN) is hydrophobic (CA~130°). (C) (Left) Surface height scan along the wedge-shaped pattern estimated the height differences across the track. (Right) three-dimensional profile of the wedge-shaped track shows differences in height between the wedge and the surrounding Teflon-coated bare AlN surface. (D) Still frames from high-speed imaging of SDPT experiments on a superhydrophilic laser-etched AlN wedge laid on a Teflon-coated hydrophobic background. The top view of the droplet transport experiment was observed with a 45° mirror (marked in the figure), while the side view is shown in the bottom half of each picture. (E) Distance traveled by the droplet front during SDPT experimentation. The three known regimes of droplet transport, as based on the slope of the curves, are marked by the vertical dashed lines.

FIG. 6 depicts profiles of surface roughness. Specifically, roughness values as measured with an optical profilometer (Keyence VHX 6000) along different lines on the herringbone wedge shaped pattern. The top profile depicts roughness scan across the path AB in the middle image. Average roughness of the coated hydrophobic Teflon is Ra=1.18 μm. The bottom profile depicts a scan across only half the hydrophilic wedge track (CD in middle image). The average roughness along that path is Ra=0.82 μm.

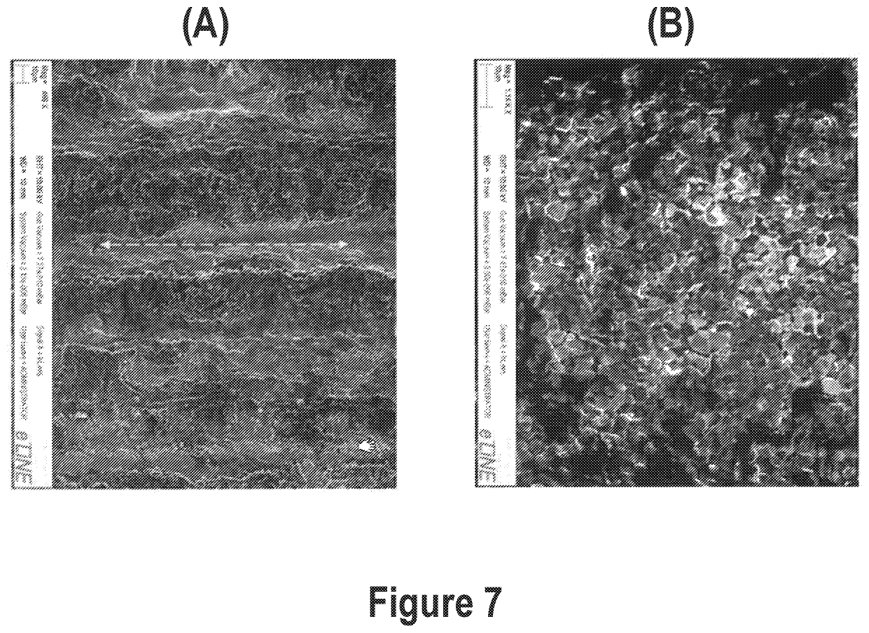

FIG. 7 includes images of AlN obtained using SEM imaging. Image (A) is a SEM image of laser-etched wedge on Teflon-coated AlN sample. Several laser beam paths (recessed) can be seen in this image, running from top to bottom; one of them has been marked lengthwise with the arrow. The scale bar at low left denotes 10 μm. Image (B) is of Teflon-coated AlN obtained using SEM. The scale bar at low left denotes 10 μm.

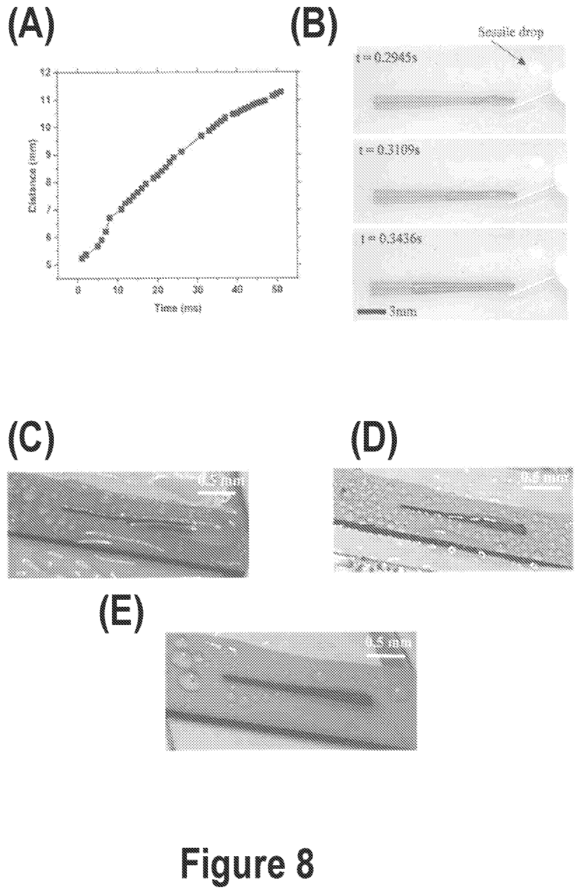

FIG. 8 includes images of fluid behavior and condensation. Image (A) depicts the distance along the wedge track vs. time plot for the motion of the advancing liquid front of a dispensed water droplet (4.5 μL) that self-propelled from the narrow to the wider end of the track on the AlN surface. Image (B) depicts a sequence of images at different time instances that capture the typical motion of a dispensed droplet on a hydrophilic wedge track (top view). Images (C), (D), and (E) are photographs showing condensation on a cooled AlN plate exposed to a water vapor rich atmosphere (Relative Humidity RH=80%). The domains of dropwise (DwC) and filmwise (FwC) condensation are visible, respectively, on the Teflon-coated (hydrophobic) and laser-etched (superhydrophilic) areas. The AlN sample (maintained at temperature Tc) was exposed to (C) Tamb=40° C., Tc=5° C., RH=80%, (D) Tamb=40° C., Tc=10° C., RH=80% and (E) Tamb=40° C., Tc=15° C., RH=80%.

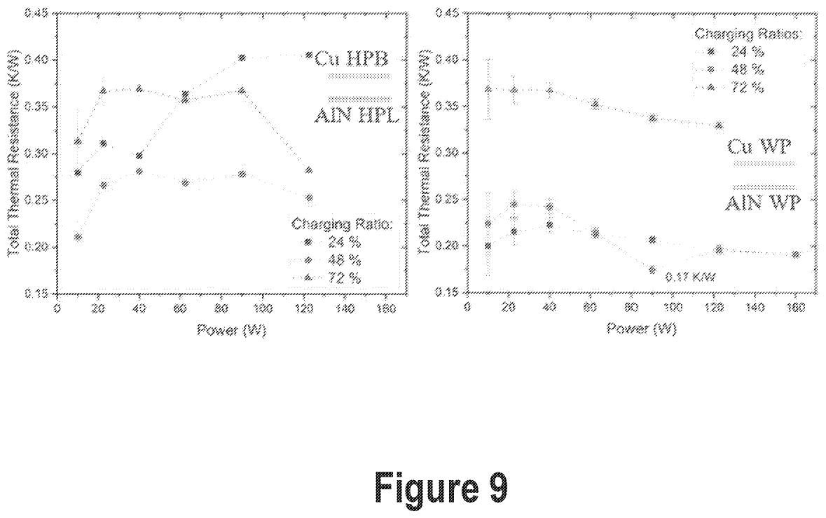

FIG. 9 illustrates the variation of overall thermal resistance for different water-charging ratios and power inputs. (A) Total thermal resistance variation for a VC with a laser-passivated hydrophilic evaporator and a Teflon-coated hydrophobic Cu. (B) Wettability patterns (WP) incorporated in the VC lead to further reduction of total thermal resistance. A low thermal resistance of 0.17 KJW was observed for the WP VC with a CR of 48%, at a power input of 90 W.

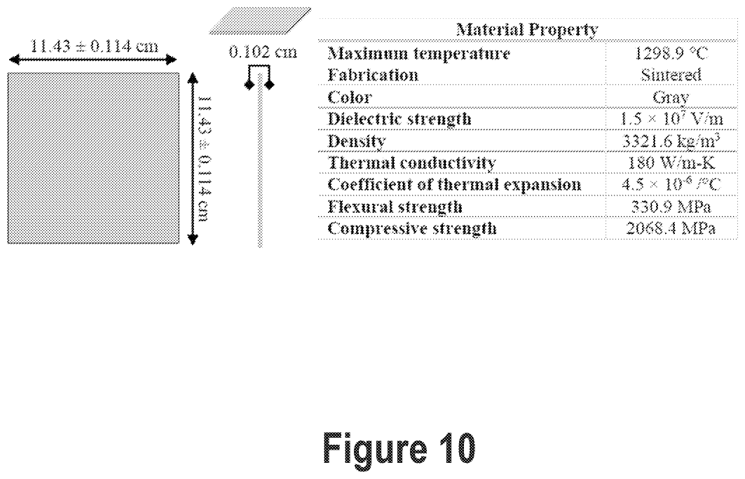

FIG. 10 depicts example material properties. In some examples, rectangular plates of AlN ceramic were sourced per the specifications of FIG. 10. To achieve the desired dimensions, samples were cut using a Disco DAD321 dicing saw operating at a blade speed of 30,000 rpm and a feed rate of 1 mm/s. In some examples, the samples underwent a cleaning process to eliminate any organic or inorganic residues that might have accrued during packaging and transportation. Initially, they were ultrasonicated in 200 Proof Ethanol (Merck Pvt. Ltd.) for 30 minutes, followed by a 10-minute ultrasonication in distilled water (Merck Life Science Pvt. Ltd.). The purity of the bulk AlN samples was assessed using X-ray diffraction (XRD) conducted on a Bruker-Nano Discover 8 instrument, alongside Energy Dispersive Spectroscopy (EDS) integrated into a field emission scanning electron microscope (FESEM: JOEL JSM-IT500HR). To ensure the integrity of the bulk samples, AlN sheets were mechanically snapped, and cross-sectional analysis was performed using SEM imaging and EDS.

### IV. CONCLUSION

The above detailed description describes various features and functions of the disclosed systems, devices, and methods with reference to the accompanying figures. In the figures, similar symbols typically identify similar components, unless context indicates otherwise. The illustrative embodiments described in the detailed description, figures, and claims are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

With respect to any or all of the message flow diagrams, scenarios, and flowcharts in the figures and as discussed herein, each step, block and/or communication may represent a processing of information and/or a transmission of information in accordance with example embodiments. Alternative embodiments are included within the scope of these example embodiments. In these alternative embodiments, for example, functions described as steps, blocks, transmissions, communications, requests, responses, and/or messages may be executed out of order from that shown or discussed, including in substantially concurrent or in reverse order, depending on the functionality involved. Further, more or fewer steps, blocks and/or functions may be used with any of the message flow diagrams, scenarios, and flow charts discussed herein, and these message flow diagrams, scenarios, and flow charts may be combined with one another, in part or in whole.

While various aspects and embodiments have been disclosed herein, other aspects and embodiments will be apparent to those skilled in the art. The various aspects and embodiments disclosed herein are for purposes of illustration and are not intended to be limiting, with the true scope being indicated by the following claims.

1. A wick-free vapor chamber comprising:
a wettability-patterned condenser configured to control vapor condensation; and
a wettability-patterned evaporator configured to: (i) accept condensate from the wettability-patterned condenser and (ii) transport the formed condensate on the wettability-patterned evaporator, wherein a surface of the wettability-patterned evaporator that is configured to accept and transport the condensate comprises a hydrophobic material disposed on a ceramic substrate, and wherein the hydrophobic material is patterned on the ceramic substrate to define the wettability pattern of the wettability-patterned evaporator.

2. The wick-free vapor chamber of claim 1, wherein the ceramic substrate comprises aluminium nitride (AlN), and wherein a surface of the AlN substrate that is configured to accept and transport the condensate comprises an oxide passivation layer.

3. The wick-free vapor chamber of claim 2, wherein the surface of the AlN substrate has a surface roughness between 0.1 μm and 200 μm.

4. The wick-free vapor chamber of claim 2, wherein the AlN substrate has a thermal conductivity between 150 Watts/meter-Kelvin (W/m-K) and 350 W/m-K.

5. The wick-free vapor chamber of claim 2, wherein the AlN substrate has a dielectric strength between 1×10⁷ Volts/meter (V/m) and 2×10⁷ V/m.

6. The wettability-patterned evaporator of claim 1, wherein the ceramic substrate comprises a non-oxide ceramic with a thermal conductivity between 100 W/m-K and 2000 W/m-K.

7. The wick-free vapor chamber of claim 6, wherein the ceramic substrate comprises silicon carbide (SiC).

8. The wick-free vapor chamber of claim 1, wherein a surface of the wettability-patterned condenser comprises a second ceramic substrate.

9. The wick-free vapor chamber of claim 1, wherein the hydrophobic material comprises a fluorinated polymer.

10. The wick-free vapor chamber of claim 1, further comprising a heat source that is thermally coupled to the ceramic substrate, wherein the wettability-patterned evaporator is configured to transport the condensate formed on the wettability-patterned evaporator to a portion of the wettability-patterned evaporator that is heated by the heat source.

11. The wick-free vapor chamber of claim 10, wherein the heat source comprises an electronic device.

12. The wick-free vapor chamber of claim 11, wherein the electronic device is fabricated on the ceramic substrate.

13. A wettability-patterned evaporator configured to: (i) accept condensate and (ii) transport the condensate on the wettability-patterned evaporator, wherein a surface of the wettability-patterned evaporator that is configured to accept and transport the condensate comprises a hydrophobic material disposed on a ceramic substrate, and wherein the hydrophobic material is patterned on the ceramic substrate to define the wettability pattern of the wettability-patterned evaporator.

14. The wettability-patterned evaporator of claim 13, wherein the ceramic substrate comprises aluminium nitride (AlN), and wherein a surface of the AlN substrate that is configured to accept and transport the condensate comprises an oxide passivation layer.

15. The wettability-patterned evaporator of claim 14, wherein the surface of the AlN substrate has a surface roughness between 0.1 μm and 200 μm.

16. The wettability-patterned evaporator of claim 14, wherein the AlN substrate has a thermal conductivity between 150 Watts/meter-Kelvin (W/m-K) and 350 W/m-K.

17. The wettability-patterned evaporator of claim 14, wherein the AlN substrate has a dielectric strength between 1×10⁷ Volts/meter (V/m) and 2×10⁷ V/m.

18. The wettability-patterned evaporator of claim 13, wherein the ceramic substrate comprises a non-oxide ceramic with a thermal conductivity between 100 W/m-K and 2000 W/m-K.

19-20. (canceled)

21. The wettability-patterned evaporator of claim 13, further comprising a heat source that is thermally coupled to the ceramic substrate, wherein the wettability-patterned evaporator is configured to transport the condensate formed on the wettability-patterned evaporator to a portion of the wettability-patterned evaporator that is heated by the heat source, wherein the heat source comprises an electronic device, and wherein the electronic device is fabricated on the ceramic substrate.

22-23. (canceled)

24. The wick-free vapor chamber of claim 1, wherein the wettability-patterned evaporator has been made by a process comprising:
processing the ceramic substrate with a laser to alter a surface roughness of a surface of the ceramic substrate to create an oxide passivation layer on the surface of the ceramic substrate;
coating the surface of the ceramic substrate with the hydrophobic material; and
patterning the hydrophobic material to create wettability patterned regions on the surface of the ceramic substrate, thereby defining the wettability pattern of the wettability-patterned evaporator.

25-30. (canceled)
